(19) United States
(12) Patent Application Publication
(10) Pub. No.: US 2022/0139932 A1
(43) Pub. Date: May 5, 2022

(54) MEMORY CELL, CAPACITIVE MEMORY STRUCTURE, AND METHODS THEREOF

(71) Applicant: Ferroelectric Memory GmbH, Dresden (DE)

(72) Inventor: Patrick Polakowski, Dresden (DE)

(21) Appl. No.: 17/085,175

(22) Filed: Oct. 30, 2020

(51) Int. Cl. H01L 27/1159; H01L 49/02; H01L 29/51; H01L 29/78; H01L 29/06; H01L 29/423; H01L 29/786; H01L 29/66

(52) U.S. Cl. CPC H01L 27/1159; H01L 28/60; H01L 29/516; H01L 29/78391; H01L 29/6684; H01L 29/42392; H01L 29/78696; H01L 29/7851; H01L 29/0673

(57) ABSTRACT

According to various aspects, a memory cell is provided, the memory cell including: a capacitive memory structure, the capacitive memory structure including a first electrode, a second electrode, and a memory structure disposed between the first electrode and the second electrode; and a field effect transistor structure, the field effect transistor structure including a gate structure coupled to the capacitive memory structure, wherein the first electrode of the capacitive memory structure includes a first electrode material having a first work-function and the second electrode of the capacitive memory structure includes a second electrode material having a second work-function, wherein the first work-function is different from the second work-function.

### TECHNICAL FIELD

Various aspects relate to a memory cell, a capacitive memory structure, and methods thereof, e.g. a method for forming a memory cell and a method for forming a capacitive memory structure.

### BACKGROUND

In general, various computer memory technologies have been developed in the semiconductor industry. A fundamental building block of a computer memory may be referred to as memory cell. The memory cell may be an electronic circuit that is configured to store at least one information (e.g., bitwise). As an example, the memory cell may have at least two memory states representing, for example, a logic “1” and a logic “0”. In general, the information may be maintained (stored) in a memory cell until the memory state of the memory cell is modified, e.g., in a controlled manner. The information stored in the memory cell may be obtained by determining in which of the memory states the memory cell is residing in. At present, various types of memory cells may be used to store data. By way of example, a type of memory cell may include a thin film of ferroelectric material, whose polarization state may be changed in a controlled fashion to store data in the memory cell, e.g. in a non-volatile manner. The memory cells may be integrated, for example, on a wafer or a chip together with one or more logic circuits.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIG. 1 shows schematically a field-effect transistor structure, according to various aspects;

FIG. 2 shows schematically an equivalent circuit diagram of a memory cell, according to various aspects;

FIG. 3A to FIG. 3E each shows schematically a memory cell, according to various aspects;

FIG. 4A shows schematically a capacitive memory structure, according to various aspects;

FIGS. 4B to 4D show various aspects of a capacitive memory structure and various properties of materials thereof, according to various aspects;

FIG. 5 shows a schematic flow diagram of a method for forming a capacitive memory structure, according to various aspects; and

FIG. 6 shows a schematic flow diagram of a method for forming a memory cell including a capacitive memory structure, according to various aspects.

### DESCRIPTION

The following detailed description refers to the accompanying drawings that show, by way of illustration, specific details and aspects in which the invention may be practiced. These aspects are described in sufficient detail to enable those skilled in the art to practice the invention. Other aspects may be utilized and structural, logical, and electrical changes may be made without departing from the scope of the invention. The various aspects are not necessarily mutually exclusive, as some aspects may be combined with one or more other aspects to form new aspects. Various aspects are described in connection with methods and various aspects are described in connection with devices (e.g., a field-effect transistor structure, a memory cell, or an electronic device). However, it may be understood that aspects described in connection with methods may similarly apply to the devices, and vice versa.

The terms “at least one” and “one or more” may be understood to include any integer number greater than or equal to one, i.e. one, two, three, four, [ . . . ], etc. The term “a plurality” or “a multiplicity” may be understood to include any integer number greater than or equal to two, i.e. two, three, four, five, [ . . . ], etc.

The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

In the semiconductor industry, the integration of non-volatile memory technologies may be useful for System-on-Chip (SoC) products like microcontrollers (MCU), etc. According to various aspects, a non-volatile memory may be integrated next to a processor core of a processor. As another example, one or more non-volatile memories may be used as part of a mass storage device. In some aspects, a non-volatile memory technology may be based on at least one field-effect transistor (FET) structure. In some aspects, a memory cell may include a field-effect transistor structure and a capacitive memory structure coupled to a gate electrode of the field-effect transistor structure. The amount of charge stored in the capacitive memory structure may influence the threshold voltage(s) of the field-effect transistor structure. The threshold voltage(s) of the field-effect transistor structure may define the memory state the memory cell is residing in. In some aspects, the capacitive memory structure may be a ferroelectric capacitor structure (FeCAP) coupled to a gate electrode of the field-effect transistor structure to provide a ferroelectric field-effect transistor (FeFET) structure. Since a ferroelectric material may have at least two stable polarization states, it may be used to shift a threshold voltage of a field-effect transistor in a non-volatile fashion; therefore, it may be used to turn the field-effect transistor into a non-volatile field-effect transistor based memory structure. A ferroelectric material may turn a ferroelectric capacitor structure into a non-volatile capacitor based memory structure, e.g. by controlling the amount of charge stored in the capacitor structure. In other aspects, a non-volatile memory technology may be based on at least one capacitive memory structure. The capacitive memory structure may be or may include a ferroelectric capacitor structure. The amount of charge stored in the capacitive memory structure may be read out by suitable electronic read out circuits, e.g., by a charge to voltage converter, by a determination of a switching current of the capacitive memory structure.

A ferroelectric field-effect transistor (FeFET) based memory cell may include two components, a transistor and a ferroelectric capacitor (FeCAP). Increasing FeFET performance may include one or more adjustments of the FeCAP layer stack. The FeCAP layer stack may include different materials, which may be adapted to increase ferroelectricity and reduce parasitic effects. A reduction of the FeCAP layer stack leakage by modification of electrode materials as well as electrode crystallographic structure may be implemented, in some aspects, to induce different crystallographic behavior in FE material.

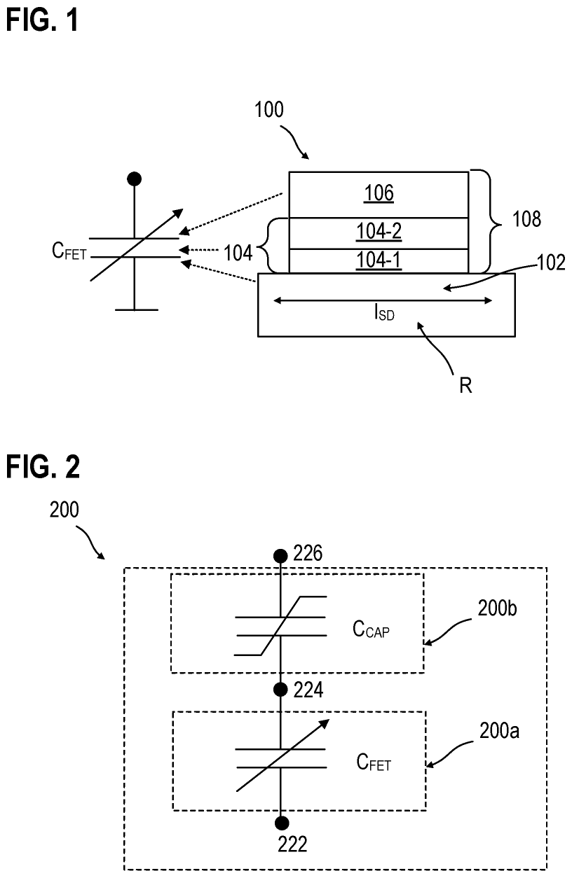

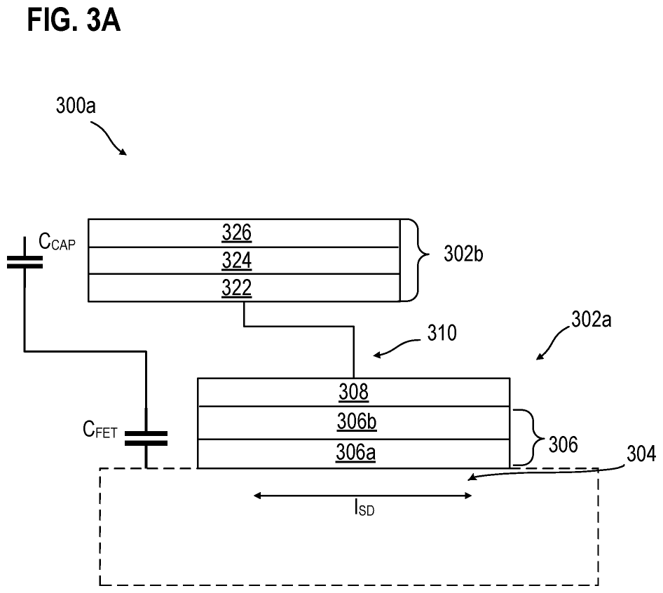

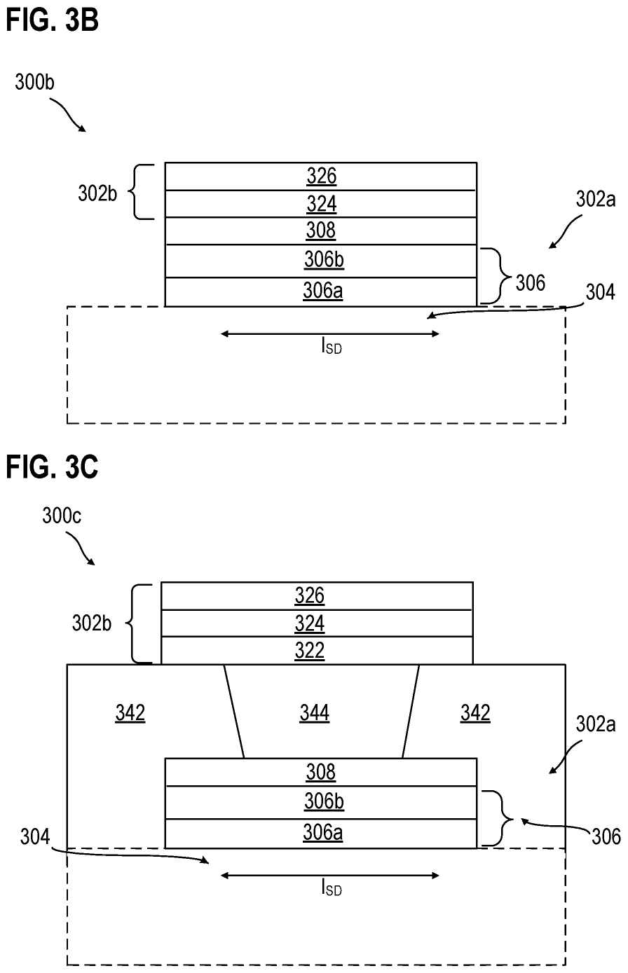

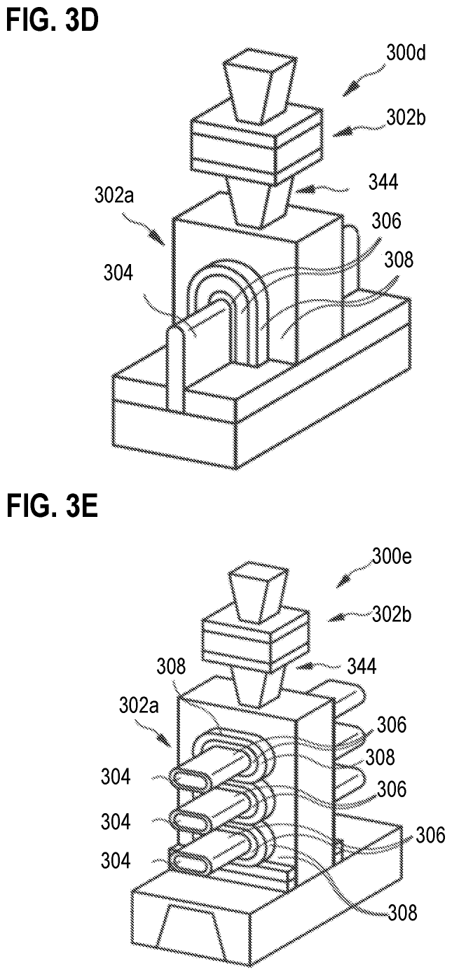

FIG. 1 shows a schematic functioning of a field-effect transistor structure 100, according to various aspects. The field-effect transistor structure 100 may include a gate structure 108, wherein the gate structure 108 may include a gate isolation 104 and a gate electrode 106. The gate structure 108 is illustrated exemplarily as a planar gate stack; however, it may be understood that the planar configuration shown in FIG. 1 is an example, and other field-effect transistor designs may include a gate structure 108 with a non-planar shape, for example a trench gate transistor design, a vertical field-effect transistor design, or other designs as exemplarily shown in FIG. 3D and FIG. 3E, as examples. The gate structure 108 may define a channel region 102, e.g., provided in a semiconductor portion (e.g., in a semiconductor layer, in a semiconductor die, etc.). The gate structure 108 may allow for a control an electrical behavior of the channel region 102. The gate structure 108 may, for example, be used to control (e.g., allow or prevent) a current flow in the channel region 102. In some aspects, the gate structure 108 may, for example, allow to control (e.g., allow or prevent) a source/drain current, I_{SD}, from a first source/drain region of the field-effect transistor structure 100 to a second source/drain region of the field-effect transistor structure 100 (the source/drains are provided in or adjacent to the channel but are not shown in FIG. 1). The channel region 102 and the source/drain regions may be formed, e.g., via doping one or more semiconductor materials or by the use of intrinsically doped semiconductor materials, within a layer and/or over a layer. In some aspects, the gate structure 108 may control (e.g., increase or reduce) an electrical resistance, R, of the channel region 102 and, accordingly, control the amount of current that may flow through the channel region 102. With respect to the operation of the field-effect transistor structure 100, a voltage (illustratively an electrical potential) may be provided at (e.g., supplied to) the gate electrode 106 to control the current flow, I_{SD}, in the channel region 102, the current flow, I_{SD}, in the channel region 102 being caused by voltages supplied via the source/drain regions.

The gate electrode 106 may include an electrically conductive material, for example, polysilicon, aluminum, etc. In some aspects, the gate electrode 106 may include any suitable electrically conductive material, e.g., a metal, a metal alloy, a degenerate semiconductor (in other words a semiconductor material having such a high level of doping that the material acts like a metal and not anymore as a semiconductor). According to various aspects, the gate electrode 106 may include one or more electrically conductive portions, layers, etc. The gate electrode 106 may include, for example, one or more metal layers (also referred to as a metal gate), one or more polysilicon layers (also referred to as poly-Si-gate), etc. A metal gate may include, for example, at least one work-function adaption metal layer disposed over the gate isolation 104 and an additional metal layer disposed over the work-function adaption metal layer. A poly-Si-gate may be, for example, p-type doped or n-type doped.

According to various aspects, the gate isolation 104 may be configured to provide an electrical separation of the gate electrode 106 from the channel region 102 and further to influence the channel region 102 via an electric field generated by the gate electrode 106. The gate isolation 104 may include one or more electrically insulating portions, layers, etc., as described in more detail below.

Some designs of the gate isolation 104 may include at least two layers including different materials, e.g., a first gate isolation layer 104-1 (e.g., a first dielectric layer including a first dielectric material) and a second gate isolation layer 104-2 (e.g., a second dielectric layer including a second dielectric material distinct from first dielectric material). The second gate isolation layer 104-2 may be disposed over the first gate isolation layer 104-1. Illustratively, the first gate isolation layer 104-1 may be disposed closer to the channel region 102 of the field-effect transistor structure 100 with respect to the second gate isolation layer 104-2. The first gate isolation layer 104-1 may be disposed directly on the channel region 102 and may provide an interface for forming the second gate isolation layer 104-2. In some aspects, the first gate isolation layer 104-1 may be referred to as buffer layer.

As illustrated by the circuit equivalent in FIG. 1, a first capacitance, C_{FET}, may be associated with the field-effect transistor structure 100. Illustratively, the channel region 102, the gate isolation 104, and the gate electrode 106 may have a capacitance, C_{FET}, associated therewith, originating from the more or less conductive regions (the channel region 102 and the gate electrode 106) separated from one another by the gate isolation 104. Further illustratively, the channel region 102 may be considered as a first capacitor electrode, the gate electrode 106 as a second capacitor electrode, and the gate isolation 104 as a dielectric medium between the two capacitor electrodes. The capacitance, C_{FET}, of the field-effect transistor structure 100 may define one or more operating properties of the field-effect transistor structure 100. The configuration of the field-effect transistor structure 100 (e.g., of the gate isolation 104) may be adapted according to a desired behavior or application of the field-effect transistor structure 100 during operation (e.g., according to a desired capacitance), as described in further detail below.

In general, the capacitance, C, of a planar capacitor structure may be expressed as,

C=ε₀εᵣA/d,

with ε₀ being the relative permittivity of the vacuum, A being the effective area of the capacitor, d being the distance of the two capacitor electrodes from one another, and εᵣ being the relative permittivity of the dielectric material disposed between two capacitor electrodes assuming that the whole gap between the two capacitor electrodes is filled with the dielectric material. It is noted that the capacitance of a non-planar capacitor structure or of a modified variant of a planar capacitor structure may be calculated based on equations known in the art.

According to various embodiments, a memory cell may be provided, for example, by coupling a gate of a field-effect transistor structure with a capacitive memory structure, or by integrating a memory structure in the gate structure of a field-effect transistor structure (as shown, for example, in FIG. 2 and FIG. 3A to FIG. 3E).

The influence of the capacitance of a field-effect transistor structure on the performance of a memory cell including a capacitive memory structure are described in further detail below.

FIG. 2 shows a circuit equivalent of a memory cell 200 including a field-effect transistor structure 200a (e.g., configured as described here with reference to the field-effect transistor structure 100) and a capacitive memory structure 200b, according to various aspects. The field-effect transistor (FET) structure 200a may have a first capacitance, C_{FET}, associated therewith and the capacitive memory structure 200b may have a second capacitance, C_{CAP}, associated therewith. The field-effect transistor structure 200a and the capacitive memory structure 200b may be coupled (e.g., electrically connected) to one another such that a capacitive voltage divider is provided. The channel or bulk node of the field-effect transistor structure 200a may provide or may be connected to a first node 222, an electrode of the capacitive memory structure 200b may provide or may be connected to a second node 226 and an intermediate conductive portion (electrode, layer, etc.) may provide or may be connected to a floating intermediate node 224. Exemplary realizations of such connected structures will be described in further detail below, for example in relation to FIG. 3A to FIG. 3E.

The capacitive voltage divider formed by the field-effect transistor structure 200a and the capacitive memory structure 200b may allow adapting the capacitances C_{FET}, C_{CAP} of the respective capacitors to allow an efficient programming of the capacitive memory structure 200b. The overall gate voltage required for switching the memory cell 200 from one memory state into another memory state (e.g. from high threshold voltage state to low threshold voltage state, as described below), may become smaller in case the voltage distribution across the field-effect transistor structure 200a and the capacitive memory structure 200b is adapted such that more of the applied gate voltage drops across the functional layer of the capacitive memory structure 200b (e.g., across a remanent-polarizable layer, such as a ferroelectric layer) than across the gate isolation of the field-effect transistor structure 200a. The overall write voltage (illustratively, applied via the nodes 222, 226 to which the field-effect transistor structure 200a and the capacitive memory structure 200b are connected) may thus be reduced by adapting the capacitive voltage divider. The voltage distribution may be determined by voltage divider calculations for a series connection of the capacitors.

That is, in case the capacitance, C_{FET}, of the field-effect transistor structure 200a is adapted (e.g., by providing a suitable gate isolation) a predefined fraction of the voltage applied to the series connection may drop across the capacitive memory structure 200b. Accordingly, the electric field generated across the gate isolation of the field-effect transistor structure 200a underneath the capacitive memory structure 200b could be reduced if desired. This may lead to a reduced interfacial field stress, which may lead to a reduced wear out of the interface due to, for example, charge injection. Therefore, the reduced electric field generated across the gate isolation may lead to improved endurance characteristics of the memory cell 200, that is, to an increased amount of possible polarization reversals until the memory cell 200 may lose or change its memory properties.

In some aspects, the functional layer of the capacitive memory structure 200b may be a remanent-polarizable layer. By increasing the capacitance C_{FET} of the field-effect transistor structure 200a (e.g., by providing a gate isolation including a relatively thick layer of material with high dielectric constant), the depolarization field, E_{Dep}, of the remanent-polarizable layer may be reduced. The depolarization field may be expressed by the following set of equations, wherein the indices “FET” refer to the capacitor provided by the field-effect transistor structure 200a and the indices “CAP” refer to the capacitor provided by the capacitive memory structure 200b, as described herein:

$${V}_{FET} + {V}_{CAP} = 0 , \\ D = {ɛ}_{0} {ɛ}_{FET} {E}_{FET} = {ɛ}_{o} {ɛ}_{CAP} {E}_{CAP} + P , \\ {E}_{CAP} ≡ {E}_{Dep} = - {P ( {ɛ}_{0} {ɛ}_{CAP} ( \frac{{C}_{FET}}{{C}_{CAP}} + 1 ) )}^{- 1} .$$

The depolarization field E_{Dep} may be detrimental to data retention since, depending on its magnitude, it may depolarize the remanent-polarizable layer. However, the magnitude may be reduced by increasing the capacitance ratio C_{FET}/C_{CAP}. Accordingly, in case the capacitance C_{FET} of the field-effect transistor structure 200a is increased, the depolarization field is reduced. This in turn improves the data retention of the memory cell 200.

In a first approximation, the voltage which drops across the memory structure capacitor, V_{CAP}, may be estimated by:

$${V}_{CAP} = {V}_{226} \cdot \frac{{C}_{FET}}{{C}_{FET} + {C}_{CAP}} ,$$

wherein V₂₂₆ represents the voltage applied to the top node 226 (e.g., to a top electrode of the capacitive memory structure 200b, for example assuming that the node 222 associated with the bulk of the field-effect transistor structure 200a is connected to a base potential, e.g. to ground or 0 V) and the capacitances in general are defined as described above. Suitable parameters for influencing the voltage drop across the capacitive memory structure 200b (e.g., across the ferroelectric capacitor) may be represented by the area ratio between the capacitive memory structure 200b and the field-effect transistor structure 200a, and/or by the relative permittivity of the field-effect transistor structure 200a (e.g., of the gate isolation of the field-effect transistor structure 200a). In some aspects, adapting the capacitance C_{FET} of the field-effect transistor structure 200a to adjust the gate voltage divider may allow keeping the thickness of the functional layer (e.g., the memory layer, e.g., a remanent-polarizable layer, e.g., a spontaneously-polarizable layer) of the capacitive memory structure 200b in a predefined range.

FIG. 3A to FIG. 3E illustrate schematically possible realizations of a respective memory cell 300a, 300b, 300c, 300d, 300e. These memory cells 300a, 300b, 300c, 300d, 300e may be configured such that a field-effect transistor structure 302a and a capacitive memory structure 302b of the respective memory cell 300a, 300b, 300c, 300d, 300e are connected to form a capacitive voltage divider C_{FET}/C_{CAP}, as described with reference to the memory cell 200 in FIG. 2. Each of the described memory cells 300a, 300b, 300c, 300d, 300e may include a field-effect transistor structure 302a including a channel 304 (also referred to herein as channel region 304), a gate isolation 306, and a gate electrode 308. The channel 304, the gate isolation 306, and the gate electrode 308 may be configured as described above, e.g., with reference to channel 102, the gate isolation 104, and the gate electrode 106 of field-effect transistor structure 100. In some aspects, the gate isolation 306 may include a first gate isolation layer 306a and a second gate isolation layer 306b. In other aspects, the gate isolation 306 may include a single gate isolation layer, i.e. one of the two gate isolation layers 306a, 306b may be omitted. The gate isolation 306 may extend from the channel region 304 to the gate electrode 308.

In some aspects, the first gate isolation layer 306a may be in direct physical contact with the channel region 304. The second gate isolation layer 306b may be in direct physical contact with the first gate isolation layer 306a and with the gate electrode 308 of the field-effect transistor structure 302a.

Each of the described memory cells 300a, 300b, 300c, 300d, 300e may include a capacitive memory structure 302b electrically connected (in other words, electrically coupled) with the field-effect transistor structure 302a. The capacitive memory structure 302b may include any type of planar or non-planar design with at least a first electrode 322, a second electrode 326 and at least one memory structure 324 disposed between the first electrode 322 and the second electrode 326, e.g. to provide memory functions. The memory structure 324 may be or may include one or more memory layers, e.g., one or more remanent-polarizable layers. However, the memory structure 324 may include other implementations of memory materials or memory structures, e.g., an anti-ferroelectric layer coupled (e.g., disposed directly on) to a charge storage layer. The charge storage layer may include any material suitable to store charge (e.g., by trapping).

As described above with reference to the memory cell 200 in FIG. 2, the field-effect transistor structure 302a and the capacitive memory structure 302b may be connected to form a capacitive voltage divider C_{FET}/C_{CAP}, e.g., by connecting one of the electrodes of the capacitive memory structure 302b (e.g., the first electrode 322) with the gate electrode 308 of the field-effect transistor structure 302a, as shown for example in FIG. 3A. The electrically conductive connection of the capacitive memory structure 302b with the field-effect transistor structure 302a (e.g., of the first electrode 322 with the gate electrode 308) may provide a series capacitive connection between the capacitors formed by the capacitive memory structure 302b and the field-effect transistor structure 302a. In a planar configuration, the first electrode 322 of the capacitive memory structure 302b may be a first capacitor electrode, the second electrode 326 may be a second capacitor electrode, and the at least one memory structure 324 may be a dielectric medium between the first electrode and the second capacitor electrode.

In some aspects, the gate electrode 308 of the field-effect transistor structure 302a may be electrically conductively connected to the first electrode 322 of the capacitive memory structure 302b via an electrically conductive (e.g., ohmic) connection 310, as shown in FIG. 3A. In some aspects, the first electrode 322 of the capacitive memory structure 302b may be in direct physical contact with the gate electrode 308 of the field-effect transistor structure 302a.

In some aspects, the capacitive memory structure 302b and the field-effect transistor structure 302a may share a common electrode acting as gate electrode of the field-effect transistor structure 302a and as electrode of the capacitive memory structure 302b, as shown in FIG. 3B.

In some aspects, the electrically conductive (e.g., ohmic) connection 310 between the field-effect transistor structure 302a and the capacitive memory structure 302b may be provided by one or more metallization structures disposed over the field-effect transistor structure 302a, as shown in FIG. 3C.

The at least one memory structure 324 may include any type of remanent-polarizable and/or spontaneously-polarizable material, e.g., a ferroelectric material, an anti-ferroelectric material, an anti-ferroelectric-like material, etc. The at least one memory structure 324 may be the functional layer of the capacitive memory structure 302b to store, for example, an information via at least two remanent polarization states of the at least one memory structure 324. The programming of the capacitive memory structure 302b (illustratively the storage of information therein) may be carried out by providing an electric field between the first electrode 322 and the second electrode 326 (e.g., an electric potential difference between a first node and a second node associated with the first electrode 322 and the second electrode 326, respectively, as described in relation to FIG. 2) to thereby set or change the remanent polarization state of the at least one memory structure 324. As an example, a voltage may be provided between the top electrode 326 and the bulk region of the field-effect transistor structure 302a.

It is understood that a memory structure 324 is only an example of a possible functional layer of the capacitive memory structure 302b, and any other functional layer whose state may be altered by an electric field provided across the capacitive memory structure 302b may be used. In some aspects, a material of the memory structure 324 may include hafnium and/or zirconium.

In general, a remanent polarization (also referred to as retentivity or remanence) may be present in a material layer in the case that the material layer may remain polarized upon reduction of an applied electric field (E) to zero, therefore, a certain value for the electrical polarization (P) of the material layer may be detected. Illustratively, a polarization remaining in a material when the electric field is reduced to zero may be referred to as remanent polarization. Therefore, the remanence of a material may be a measure of the residual polarization in the material in the case that an applied electric field is removed. In general, ferroelectricity and anti-ferroelectricity may be concepts to describe a remanent polarization of a material similar to ferromagnetism and anti-ferromagnetism used to describe remanent magnetization in magnetic materials.

According to various aspects, a ferroelectric material may be used as part of a capacitive memory structure of a memory cell (e.g., as part of the capacitive memory structure 302b of a memory cell 300a, 300b, 300c, 300d, 300e, or of the capacitive memory structure 200b of the memory cell 200). A ferroelectric material may be an example of material of a remanent-polarizable layer (e.g., of the memory structure 324). Illustratively, ferroelectric materials may be used to store data in non-volatile manner in integrated circuits. The term “ferroelectric” may be used herein, for example, to describe a material that shows a hysteretic charge voltage relationship (Q-V). The ferroelectric material may be or may include at least one of the following: hafnium oxide (ferroelectric hafnium oxide, HfO₂), zirconium oxide (ferroelectric zirconium oxide, ZrO₂), a (ferroelectric) mixture of hafnium oxide and zirconium oxide. Ferroelectric hafnium oxide may include any form of hafnium oxide that may exhibit ferroelectric properties. Ferroelectric zirconium oxide may include any form of zirconium oxide that may exhibit ferroelectric properties. This may include, for example, hafnium oxide, zirconium oxide, a solid solution of hafnium oxide and zirconium oxide (e.g. but not limited to it a 1:1 mixture) or hafnium oxide and/or zirconium oxide doped or substituted with one or more of the following elements (non-exhaustive list): silicon, aluminum, gadolinium, yttrium, lanthanum, strontium, zirconium, any of the rare earth elements or any other dopant (also referred to as doping agent) that is suitable to provide or maintain ferroelectricity in hafnium oxide or zirconium oxide. The ferroelectric material may be doped at a concentration from about 2 mol % to about 6 mol %, only as an example.

According to various aspects, a memory cell (e.g., a memory cell 200, 300a, 300b, 300c, 300d, 300e), may have at least two distinct states associated therewith, for example with two distinct electrical conductivities or two distinct amounts of stored charge that may be determined to determine in which of the at least two distinct states the memory cell is residing in. According to various aspects, a memory state the memory cell is residing may be a “programmed state” or an “erased state”. As an example, the programmed state may be an electrically conducting state or a state with positive stored charge (e.g. associated with a logic “1”) and the erased state may be an electrically non-conducting state or a state with negative stored charge (e.g., associated with a logic “0”). However, the definition of programmed state and erased state may be selected arbitrarily.

According to various aspects, the residual polarization of the remanent-polarizable layer may define the memory state a memory cell is residing in. The polarization state of the remanent-polarizable layer may be switched by means of the capacitive memory structure. The polarization state of the remanent-polarizable layer may also be read out by means of the capacitive memory structure. According to various aspects, a memory cell may reside in a first memory state in the case that the remanent-polarizable layer is in a first polarization state, and the memory cell may reside in a second memory state in the case that the remanent-polarizable layer is in a second polarization state (e.g., opposite to the first polarization state). As an example, the polarization state of the remanent-polarizable layer may determine the amount of charge stored in the capacitive memory structure. The amount of charge stored in the capacitive memory structure may be used to define a memory state of the memory cell. The threshold voltage of a field-effect transistor structure (e.g., the field-effect transistor structure 200a, the field-effect transistor structure 302a) may be a function of the amount and/or polarity of charge stored in the capacitive memory structure, e.g. on the polarization state of the remanent-polarizable layer. A first threshold voltage, e.g. a high threshold voltage V_{H-th}, may be associated with the first polarization state (e.g., with the first amount and/or polarity of stored charge), and a second threshold voltage, e.g. a low threshold voltage V_{L-th}, may be associated with the second polarization state (e.g., with the second amount and/or polarity of stored charge). Illustratively, the first memory state may be associated with the first threshold voltage, and the second memory state may be associated with the second threshold voltage.

According to various aspects, the second gate isolation layer 306b of the gate isolation 306 of the field-effect transistor structure 302a may be a layer different from a functional layer of the capacitive memory structure 302b (e.g., different from the memory structure 324), e.g. different in at least one of the type of material(s) or the remanent-polarizable properties of the material(s). By way of example, the material of the second gate isolation layer 306b may not possess remanent-polarizable properties, e.g. it may not possess ferroelectric properties.

According to various aspects, the semiconductor portion (illustratively, where the channel region 304 may be formed), may be made of or may include silicon. However, other semiconductor materials of various types may be used in a similar way, e.g. germanium, Group III to V (e.g. SiC), or other types, including for example carbon nanotubes, organic materials (e.g., organic polymers), etc. In various aspects, the semiconductor portion may be a wafer made of silicon (e.g. p-type doped or n-type doped). In other aspects, the semiconductor portion may be a silicon on insulator (SOI) wafer. In other aspects, the semiconductor portion may be provided by a semiconductor structure, e.g., by one or more semiconductor fins, one or more semiconductor nanosheets, one or more semiconductor nanowires, etc., disposed at a carrier.

FIG. 3C shows an exemplary integration scheme for a memory cell 300c in a schematic view, according to various aspects, in which a metallization structure is provided to electrically connect the field-effect transistor structure 302a to the capacitive memory structure 302b. It is understood that the metallization structure may include a plurality of metallization structures, e.g. a plurality of single- or multi-level contact structures.

The metallization structure may be configured to electrically conductively connect the gate electrode 308 of the field-effect transistor structure 302a and the first electrode 322 of the capacitive memory structure 302b with one another. As an example, the metallization structure may include a contact metallization. The contact metallization may be at least partially disposed between the field-effect transistor structure 302a and the capacitive memory structure 302b. As another example, the metallization structure may include a contact metallization and a single- or multi-level metallization disposed over the contact metallization. In this case, both the contact metallization and at least one level of the single- or multi-level metallization may be disposed between the field-effect transistor structure 302a and the capacitive memory structure 302b.

The metallization structure may include a gate contact structure 344 (also referred to as gate contact). The gate contact structure 344 may be embedded in (e.g., may be laterally surrounded by) an insulator layer 342. The insulator layer 342 may include a dielectric material, e.g., silicon oxide (SiO₂), silicon nitride (SiNₓ), etc., having, for example, a thickness in the range from about 10 nm to about 100 nm, e.g., a thickness of 40 nm. In some aspects, the insulator layer 342 may include a plurality of insulator layers, e.g. each including a same material or different materials. The gate contact structure 344 may include at least one metal layer, e.g., including tungsten (W), cobalt (Co), etc. The gate contact structure 344 may be in direct physical contact with the gate electrode 308 of the field-effect transistor structure 302a. The gate contact structure 344 may be in direct physical contact with the first electrode 322 of the capacitive memory structure 302b. According to various aspects, the electrical connection between the first electrode 322 of the capacitive memory structure 302b and the gate electrode 308 of the field-effect transistor structure 302a may be formed by the gate contact structure 344.

A further metallization structure (shown, for example, in FIG. 3D and FIG. 3E) may be formed over the capacitive memory structure 302b. The further metallization structure may include a memory contact structure (also referred to as memory contact). The memory contact structure may be embedded in (e.g., may be laterally surrounded by) a further (e.g., second) insulator layer.

FIG. 3D and FIG. 3E illustrate possible non-planar structures for a memory cell 300d, 300e, e.g. for a field-effect transistor structure 302a (e.g., for a memory transistor described above).

In the integration scheme shown in FIG. 3D, at least the field-effect transistor structure 302a of the memory cell 300d may be configured as a fin field-effect transistor (FinFET). The semiconductor portion in which the channel region 304 is provided may have the shape of a vertical fin, wherein the gate isolation 306 and the gate electrode 308 may at least partially surround the fin.

In the integration scheme shown in FIG. 3E, at least the field-effect transistor structure 302a of the memory cell 300e may be configured as a nanosheet or nanowire field-effect transistor. The one or more semiconductor portions, in which a channel region 304 is provided, may each have the shape of a nanosheet or nanowire. The gate isolation 306 and the gate electrode 308 may at least partially surround the respective nanosheets or nanowires.

For ferroelectric HfO₂, its ferroelectric properties may likely disappear when the layer thickness is reduced to below 2 nm or at least when the reduction in film thickness leads to an unacceptable increase of the crystallization temperature such that the ferroelectric phase in HfO₂ cannot be stabilized anymore. Therefore, according to various aspects, a layer thickness for a ferroelectric HfO₂ layer used in a capacitive memory structure may be selected greater than or equal to 2 nm. For the most advanced transistor platforms, e.g., illustrated exemplarily in FIG. 3D and FIG. 3E, it may be beneficial to arrange the ferroelectric HfO₂ layer above the field-effect transistor structure, so that the ferroelectric HfO₂ layer can be implemented with the desired layer thickness in these process platforms.

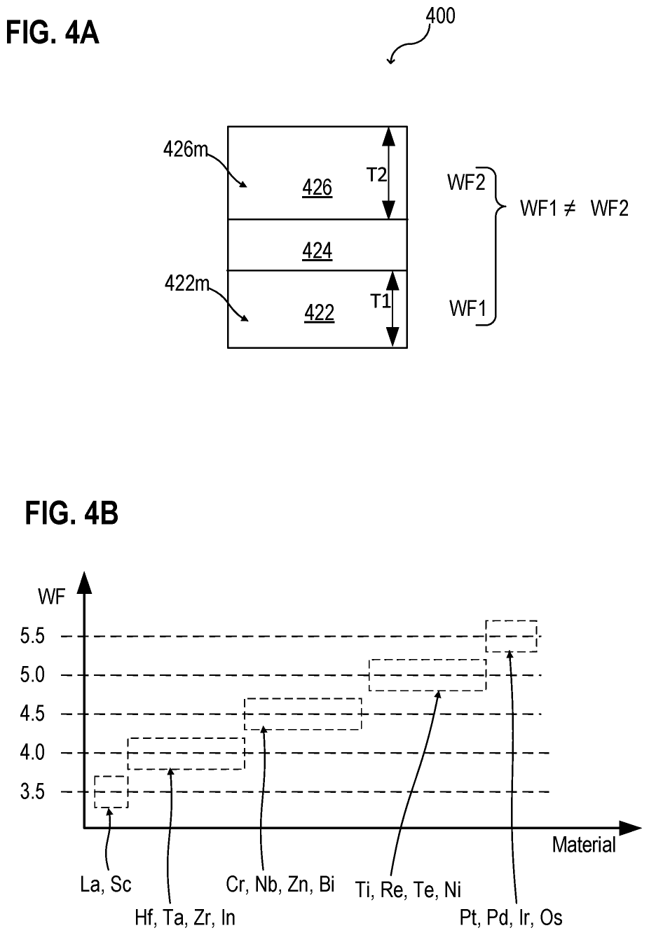

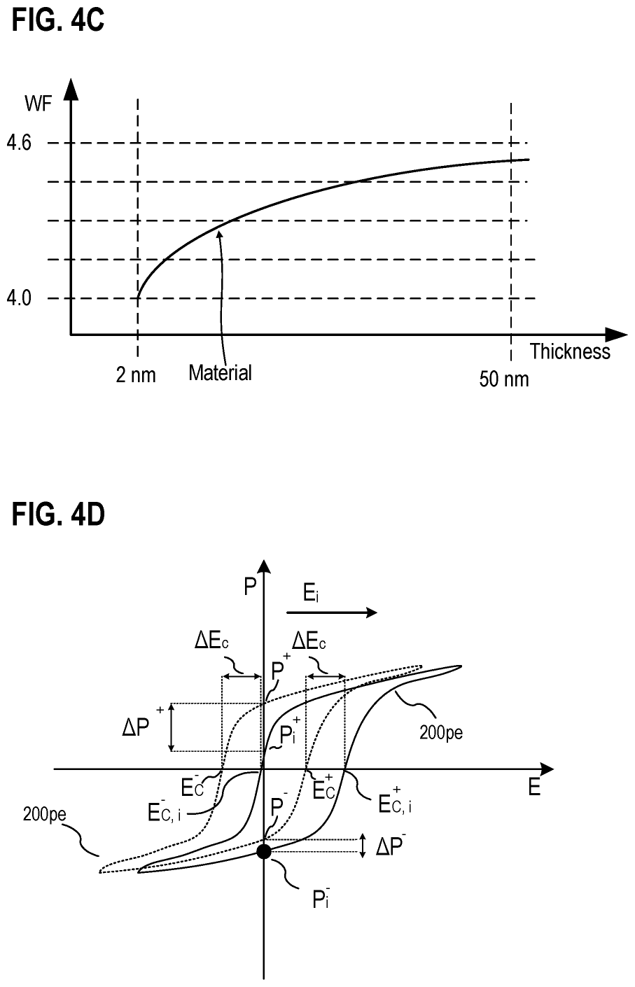

FIG. 4A illustrates a capacitive memory structure 400 in a schematic view, in accordance with various aspects. The capacitive memory structure 400 may include a first electrode 422. The first electrode 422 may include a first electrode material 422m having a first work-function WF1 associated therewith. In some aspects, the first electrode 422 may include a single layer of the first electrode material 422m. In other aspects, the first electrode 422 may include a multilayer layer including one or more materials that form the first electrode material 422m. The capacitive memory structure 400 may include a second electrode 426. The second electrode 426 may include a second electrode material 426m having a second work-function WF2 associated therewith. In some aspects, the second electrode 426 may include a single layer of the second electrode material 426m. In other aspects, the second electrode 426 may include a multilayer layer including one or more materials that form the second electrode material 426m. According to various aspects, the first work-function WF1 of the first electrode material 422m is different from the second work-function WF2 of the second electrode material 426m.

According to various aspects, a memory structure 424 is disposed between the first electrode 422 and the second electrode 426. In some aspects, the memory structure 424 may include one or more remanent polarizable layers. The memory structure 424 may allow storage of data based on polarizing (remanently) one or more layers including one or more suitable materials or a suitable combination of materials. In other aspects, the memory structure 424 may include one or more charge storage layers. The memory structure 424 may allow storage of data based on charging (e.g., permanently) one or more charge storage layers including one or more suitable materials or a suitable combination of materials. In still other aspects, the memory structure 424 may include one or more charge storage layers and one or more polarizable layers, e.g., one or more spontaneously polarizable layers (e.g., one or more anti-ferroelectric layers). The memory structure 424 may allow storage of data based on charging (e.g., permanently) one or more charge storage layers assisted by the one or more polarizable layers.

According to various aspects, a first thickness T1 of the first electrode 422 and/or a second thickness T2 of the second electrode 426 may be configured to adapt the work-function WF1, WF2 of the first electrode material 422m and the second electrode material 426m respectively. In some aspects, the first thickness T1 of the first electrode 422 and the second thickness T2 of the second electrode 426 may be selected to provide a predefined difference in the work-functions WF1, WF2. In some aspects, the first thickness T1 of the first electrode 422 may be greater than the second thickness T2 of the second electrode 426 to provide a predefined difference in the work-functions WF1, WF2. In other aspects, the first thickness T1 of the first electrode 422 may be less than the second thickness T2 of the second electrode 426 to provide a predefined difference in the work-functions WF1, WF2. An absolute value of a thickness difference (|T1−T2|=|T2−T1|) may be in the range from about 1 nm to about 10 μm, e.g., in the range from about 10 nm to about 1 μm.

Selecting the respective electrode materials 422m, 426m and/or selecting the respective thicknesses T1, T2 of the electrodes 422, 426 of the capacitive memory structure 400 may allow an adaptation of the work-function difference. As an example, one or more memory properties of the capacitive memory structure 400 (e.g., hysteresis properties, e.g., the shape and/or position of the hysteresis curve) or of a memory cell including a capacitive memory structure 400 (e.g., the position of the memory window) may be configured by adapting the electrodes 422, 426 with respect to the work-function difference, as explained in more detail below, see FIG. 4B to FIG. 4D. The work-function difference may cause in internal electric field in the capacitive memory structure 400 that may shift the polarization properties and/or that may change the hysteresis properties.

According to various aspects, an absolute value of a difference of the first work-function and the second work-function (|WF1−WF2|=|WF2−WF1|) may be greater than 0.1 electron-volts (eV). In some aspects, the absolute value of a difference of the first work-function and the second work-function (|WF1−WF2|=|WF2−WF1|) may be less than 4 electron-volts. In some aspects, the work-function WF1 of the first electrode 422 and the second work-function WF2 of the second electrode 426 may be selected to provide a predefined difference (|WF1−WF2|=|WF2−WF1|) in the work-functions WF1, WF2. In some aspects, the first work-function WF1 of the first electrode 422 may be greater than the second work-function WF2 of the second electrode 426 to provide a predefined difference (|WF1−WF2|=|WF2−WF1|) in the work-functions WF1, WF2. In some aspects, the first work-function WF1 of the first electrode 422 may be less than the second work-function WF2 of the second electrode 426 to provide a predefined difference (|WF1−WF2|=|WF2−WF1|) in the work-functions WF1, WF2.

According to various aspects, the capacitive memory structure 400 may be coupled to a field-effect transistor structure (e.g., to a field-effect transistor structure 100, 200a, 302a as described herein with reference to FIGS. 1 to 3E or to another suitable field-effect transistor structure) to form a capacitive voltage divider, see, for example, FIG. 2.

According to various aspects, the first electrode material 422m may include a basic material (e.g., TiN or any other suitable electrically conductive material) having a work-function WF associated therewith and a first doping material (e.g., Pt, Ir, Re, Rh, Ti, Os, Mo, Ru, Cr, W, as examples) that increases the work-function of the basic material.

According to various aspects, the second electrode material 426m may include a basic material (e.g., TiN or any other suitable electrically conductive material) having a work-function WF associated therewith and a first doping material (e.g., Pt, Ir, Re, Rh, Ti, Os, Mo, Ru, Cr, W, as examples) that increases the work-function of the basic material.

According to various aspects, the first electrode material 422m may include a basic material (e.g., TiN or any other suitable electrically conductive material) having a work-function WF associated therewith and a first doping material (e.g., La, Hf, Ta, Zr, In, Cd, Ag, Al, V, Nb, Sn, Zn, as examples) that decreases the work-function of the basic material.

According to various aspects, the second electrode material 426m may include a basic material (e.g., TiN or any other suitable electrically conductive material) having a work-function WF associated therewith and a first doping (e.g., La, Hf, Ta, Zr, In, Cd, Ag, Al, V, Nb, Sn, Zn, as examples) that decreases the work-function of the basic material.

In the following, various work-functions are described for corresponding materials, as examples. Ag (WF=4.5); Al (WF=4.2); As (WF=3.8); Au (WF=5.3); B (WF=4.5); Ba (WF=2.6); Be (WF=5.0); Bi (WF=4.3); C (WF=5); Ca (WF=2.87); Cd (WF=4.1); Ce (WF=2.9); Co (WF=5); Cr (WF=4.5); Cs (WF=2.0); Cu (WF=4.8); Eu (WF=2.5); Fe (WF=4.7); Ga (WF=4.3); Gd (WF=2.9); Hf (WF=3.9); Hg (WF=4.5); In (WF=4.1); Ir (WF=5.3); K (WF=2.3); La (WF=3.5); Li (WF=2.9); Lu (WF=3.3); Mg (WF=3.7); Mn (WF=4.1); Mo (WF=4.7); Na (WF=2.4); Nb (WF=4.4); Nd (WF=3.2); Ni (WF=5.2); Os (WF=5.9); Pb (WF=4.3); Pd (WF=5.5); Pt (WF=5.5); Rb (WF=2.3); Re (WF=4.7); Rh (WF=5.0); Ru (WF=4.7); Sb (WF=4.6); Sc (WF=3.5); Se (WF=5.9); Si (WF=4.7); Sm (WF=2.7); Sn (WF=4.4); Sr (WF=2.5); Ta (WF=4.4); Tb (WF=3.0); Te (WF=5.0); Th (WF=3.4); Ti (WF=4.3); Tl (WF=3.8); V (WF=4.3); W (WF=4.7); Y (WF=3.1); Yb (WF=2.6); Zn (WF=4.4); Zr (WF=4.1). FIG. 4B illustrates various work-functions (perpendicular axis) associated with one or more materials (horizontal axis), according to various aspects.

According to various aspects, the first electrode 422 may be a multilayer electrode including one or more layers of a first material and one or more layers of a second material, wherein a work-function of the first material is different from a work-function of the second material. According to various aspects, the second electrode 426 may be a multilayer electrode including one or more layers of a first material and one or more layers of a second material, wherein a work-function of the first material is different from a work-function of the second material. This may allow mixtures of materials to implement the desired work-function for the total layer stack formed from the one or more layers. According to various aspects, a layer thickness below, for example, 50 nm may have an influence on the work-function of a material, e.g., the work-function may decrease (e.g., in the range from about 1% to about 30%; e.g., in the range from about 0.1 eV to about 1 eV) with decreasing layer thickness, e.g., due to thin film effects. FIG. 4C illustrates schematically a behavior of a work-functions (perpendicular axis) associated with one or more materials in dependence of the layer thickness (horizontal axis) of such a material, according to various aspects.

According to various aspects, a doped and/or intermixed electrode material may be used to provide the electrode material for the first and second electrode 422, 426 of the capacitive memory structure 400 with the desired work-functions. The work function WF for a given material and surface may be described by the following equation:

WF=−eφ−E_{F},

wherein “e” is the charge of an electron, “φ” is the electrostatic potential in the vacuum nearby the surface, and “E_{F}” is the Fermi-level (in other words the electrochemical potential of electrons) inside the material. Illustratively, the term “−e φ” may represent an energy of an electron at rest in the vacuum nearby the surface of the material.

It is noted that various conditions may influence the value of the work-function of a material. In some aspects, values of the work-function may be averaged considering microscopic effects. However, there may be many techniques available to determine the electronic work function of a sample of a material; e.g., electron emission induced by photon absorption (photoemission), electron emission induced by temperature (thermionic emission), electron emission induced by an electric field (field electron emission), or electron emission induced by electron tunneling. Relative determinations may be possible as well, e.g., based on the Kelvin Probe method or Kelvin probe force microscope).

FIG. 4D shows a polarization characteristic of a remanent-polarizable layer, according to various aspects. In some aspects, an internal field, Eᵢ, may be generated in the capacitive memory structure 400 that allows for hysteresis position tuning, as described in more detail below.

In the graph shown in FIG. 4D, the polarization, P, is plotted as a function of an applied electric field, E. A remanent-polarizable layer may exhibit a hysteretic behavior illustrated in form of a measured hysteresis loop 200pe. For increasing (positive or negative) applied electric field, E, the polarization, P, of the remanent-polarizable layer may increase accordingly (illustratively, it may become more positive or more negative). When the field, E, is no longer applied (e.g. E=0), the polarization, P, does not vanish, but a residual polarization remains in the remanent-polarizable layer, for example a first (e.g., positive) residual polarization, P⁺, or a second (e.g., negative) residual polarization, P⁻. The sign of the residual polarization may depend on whether the applied field, E, exceeds a respective threshold value (e.g., a positive coercive field, E_{C}⁺, or a negative coercive field, E_{C}⁻).

According to various aspects, FIG. 4D illustrates an exemplary condition of a remanent-polarizable layer without any internal field, see dotted lines. In this case, the remanent-polarizable layer may have predefined residual polarizations, e.g., P⁺, P⁻, predefined coercive fields, E_{C}⁺, E_{C}⁻, as example.

According to various aspects, due to an internal electric field, Eᵢ, that may be caused by adapted work-functions of electrodes of a capacitive memory structure (e.g., caused by a difference in the work-functions of the electrode materials), the polarization properties of the remanent-polarizable layer may be modified, e.g., shifted (see the solid lines). Illustratively, the value of the first coercive field, E_{C}⁺, may be shifted to a modified value of the first (e.g., positive) coercive field, E_{C,I}⁺, and the value of the second coercive field, E_{C}⁻, may be shifted to a modified value of the second (e.g., negative) coercive field, E_{C,I}⁻. Moreover, the value of the first residual polarization, P⁺, of the remanent-polarizable layer may be shifted to a modified value of the first (e.g., positive) residual polarization, P_{I}⁺, and the value of the second residual polarization, P⁻, may be shifted to a modified value of the second (e.g., negative) residual polarization, P_{I}⁻. Illustratively, an actual value of the coercive field(s) and of the residual polarization(s) may be different from the respective values for a case in which the electrodes of the capacitive memory structure have the same work-functions.

In some aspects, other effects may influence the polarization properties of a capacitive memory structure. As an example, imprinting effects or other effects may shift the polarization curve of a remanent-polarizable layer. In this view, the work-functions (and therefore the work-function difference) may be selected to compensate for such undesired effects. Illustratively, in the case that the polarization curve (or hysteresis loop) may be shifted to higher or lower electric fields, the work-functions (and therefore the work-function difference) may be selected such that the polarization curve (or hysteresis loop) is shifted back for substantially the same amount. Therefore, optimal operation points may be provided for one or more capacitive memory structures and/or one or more memory cells including one or more capacitive memory structures.

According to various aspects, in the case that the electrode material of one or more of the electrodes of the capacitive memory structure may include a dopant to influence the work-function, an optional configuration may include providing a dopant concentration gradient within the electrode material.

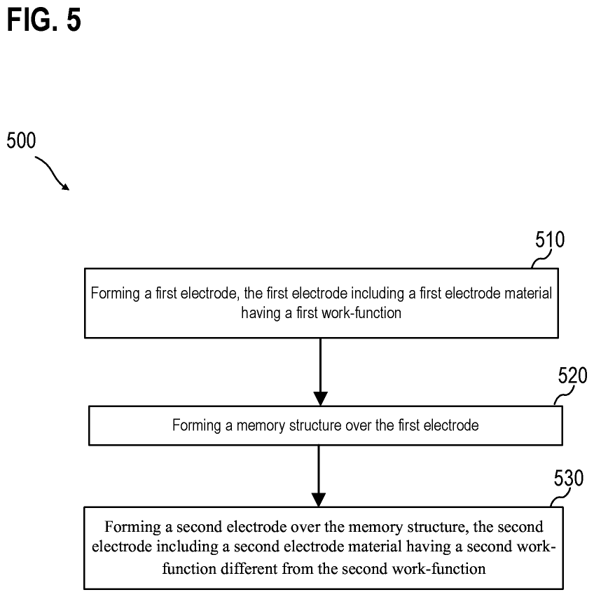

FIG. 5 illustrates a schematic flow diagram of a method 500 for forming a capacitive memory structure, according to various aspects. In some aspects, the method 500 for forming a capacitive memory structure may include one or more processes configured to form the capacitive memory structure 400, as described herein.

According to various aspects, the method 500 for forming a capacitive memory structure may include: in 510, forming a first electrode, the first electrode including a first electrode material having a first work-function. In some aspects, the first electrode formed in process 510 of the method 500 may include a first electrode material 422m having a first work-function WF1, as described herein.

According to various aspects, the method 500 for forming a capacitive memory structure may include: in 520, forming a memory structure over the first electrode. In some aspects, the memory structure formed in process 520 of the method 500 may include a memory structure 424, as described herein.

According to various aspects, the method 500 for forming a capacitive memory structure may include: in 530, forming a second electrode over the memory structure, the second electrode including a second electrode material having a second work-function different from the second work-function. In some aspects, the second electrode formed in process 530 of the method 500 may include a second electrode material 426m having a second work-function WF2, as described herein.

In some aspects, the first electrode, the memory structure, and the second electrode formed in processes 510, 520, 530 of method 500 may form a capacitive memory structure. In some aspects, the capacitive memory structure formed in processes 510, 520, 530 of the method 500 may include a capacitive memory structure 400, as described herein.

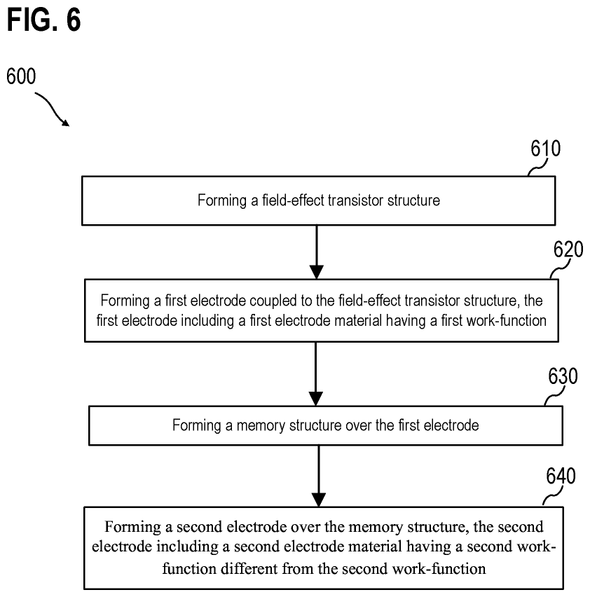

FIG. 6 illustrates a schematic flow diagram of a method 600 for forming a memory cell, according to various aspects. In some aspects, the method 600 for forming a memory cell may include one or more processes configured to form the memory cell 200, 300a, 300b, 300c, 300d, 300e, as described herein, including a capacitive memory structure 400 as the capacitive memory structure 200b, 302b.

According to various aspects, the method 600 for forming a memory cell may include: in 610, forming a field-effect transistor structure. The field-effect transistor structure may include a gate structure, e.g., including a gate isolation and a gate electrode. The field-effect transistor structure formed in process 610 of the method 600 may be configured in the same or in a similar way as the field-effect transistor structure 100, 200a, 302a. In some aspects, the field-effect transistor structure formed in process 610 of the method 600 may include a gate structure 108, e.g., including a gate isolation 104, 306 and a gate electrode 106, 308 as described herein.

According to various aspects, the method 600 for forming a memory cell may include: in 620, forming a first electrode, the first electrode including a first electrode material having a first work-function. The first electrode being coupled (e.g., electrically conductively connected, e.g., in direct physical contact, as examples) with the field-effect transistor structure, e.g., with the gate structure of the field-effect transistor structure, e.g., with the gate electrode of the field-effect transistor structure. In some aspects, the first electrode formed in process 620 of the method 600 may include a first electrode material 422m having a first work-function WF1, as described herein.

According to various aspects, the method 600 for forming a memory cell may include: in 630, forming a memory structure over the first electrode. In some aspects, the memory structure formed in process 630 of the method 600 may include a memory structure 424, as described herein.

According to various aspects, the method 600 for forming a memory cell may include: in 640, forming a second electrode over the memory structure, the second electrode including a second electrode material having a second work-function different from the second work-function. In some aspects, the second electrode formed in process 640 of the method 600 may include a second electrode material 426m having a second work-function WF2, as described herein.

In some aspects, the first electrode, the memory structure, and the second electrode formed in processes 620, 630, 640 of method 600 may form a capacitive memory structure. In some aspects, the capacitive memory structure formed in processes 620, 630, 640 of the method 600 may include a capacitive memory structure 400, as described herein.

According to various aspects, forming the first electrode 510, 620 may include: depositing the first electrode material. According to various aspects, forming the first electrode 510, 620 may include: depositing a basic material and modifying the basic material to thereby form the first electrode material. According to various aspects, forming the second electrode 530, 640 may include: depositing the second electrode material. According to various aspects, forming the second electrode 530, 640 may include: depositing a basic material and modifying the basic material to thereby form the second electrode material. In some aspects, modifying the basic material may include at least one of: doping the basic material with one or more dopants; intermixing the basic material with one or more additional materials; implanting ions into the basic material; modifying the microstructure of the basic material; modifying the surface roughness of the basic material; removing a portion of the basic material; and/or modifying the crystallographic phase of the basic material.

According to various aspects, forming the first electrode 510, 620 may include: forming the first electrode by forming one or more first electrode layers with a predefined total thickness and having the first work-function associated therewith. According to various aspects, forming the second electrode 530, 640 may include: forming the second electrode by forming one or more second electrode layers with a predefined total thickness and having the second work-function associated therewith.

According to various aspects, a memory cell 200, 300a, 300b, 300c, 300d, 300e may include: a capacitive memory structure 400, the capacitive memory structure 400 may include a first electrode 422, a second electrode 426, and a memory structure 424 disposed between the first electrode 422 and the second electrode 426; and a field-effect transistor structure 100, 200a, 302a, the field-effect transistor structure 100, 200a, 302a may include a gate structure 108 coupled to the capacitive memory structure 400. Further, the first electrode 422 of the capacitive memory structure 400 may include a first electrode material 422m having a first work-function WF1 and the second electrode 426 of the capacitive memory structure 400 may include a second electrode material 426m having a second work-function WF2, wherein the first work-function WF1 is different from the second work-function WF2.

According to various aspects, memory cell 200, 300a, 300b, 300c, 300d, 300e may have an enhanced retention compared to a memory cell having a capacitive memory structure that has no internal electric field provided by adapting the work-functions of the respective electrodes. In some aspects, the depolarization field, E_{Dep}, may be reduced by an internal electric field generated by electrodes of the capacitive memory structure 400 having different work-functions and therefore a work-function-difference associated therewith.

According to various aspects, a memory cell as described herein may be integrated in an electronic device (e.g., e.g., a microcontroller, a central processing unit, a system on a chip (SoC), a memory device), for example in a same electronic device with other components, such as components to control logic operations and/or input/output operations of the electronic device. Illustratively, one or more memory transistors may be integrated (and formed) on or in a same carrier as one or more logic transistors and/or one or more input/output transistors.

The word “over”, used herein to describe forming a feature, e.g. a layer “over” a side or surface, may be used to mean that the feature, e.g. the layer, may be formed “directly on”, e.g. in direct contact with, the implied side or surface. The word “over”, used herein to describe forming a feature, e.g. a layer “over” a side or surface, may be used to mean that the feature, e.g. the layer, may be formed “indirectly on” the implied side or surface with one or more additional layers being arranged between the implied side or surface and the formed layer.

The term “lateral” used with regards to a lateral dimension (in other words a lateral extent) of a structure, a portion, a structure element, a layer, etc., provided, for example, over and/or in a carrier (e.g. a layer, a substrate, a wafer, etc.) or “laterally” next to, may be used herein to mean an extent or a positional relationship along a surface of the carrier. That means, in some aspects, that a surface of a carrier (e.g. a surface of a layer, a surface of a substrate, a surface of a wafer, etc.) may serve as reference, commonly referred to as the main processing surface. Further, the term “width” used with regards to a “width” of a structure, a portion, a structure element, a layer, etc., may be used herein to mean the lateral dimension (or in other words the lateral extent) of a structure. Further, the term “height” used with regards to a height of a structure, a portion, a structure element, a layer, etc., may be used herein to mean a dimension (in other words an extent) of a structure in a direction perpendicular to the surface of a carrier (e.g. perpendicular to the main processing surface of a carrier).

The term “connected” may be used herein with respect to nodes, terminals, integrated circuit elements, and the like, to mean electrically connected, which may include a direct connection or an indirect connection, wherein an indirect connection may only include additional structures in the current path that do not influence the substantial functioning of the described circuit or device. The term “electrically conductively connected” that is used herein to describe an electrical connection between one or more terminals, nodes, regions, contacts, etc., may be understood as an electrically conductive connection with, for example, ohmic behavior, e.g. provided by a metal or degenerate semiconductor in absence of p-n junctions in the current path. The term “electrically conductively connected” may be also referred to as “galvanically connected”.

The term region used with regards to a “source region”, “drain region”, “channel region”, and the like, may be used herein to mean a continuous region of a semiconductor portion (e.g., of a semiconductor wafer or a part of a semiconductor wafer, a semiconductor layer, a fin, a semiconductor nanosheet, a semiconductor nanowire, etc.,). In some aspects, the continuous region of a semiconductor portion may be provided by semiconductor material having only one dominant doping type.

The term “thickness” used with regards to a “thickness” of a layer may be used herein to mean the dimension (in other words an extent) of the layer perpendicular to the surface of the support (the material or material structure) on which the layer is formed (e.g., deposited or grown). If a surface of the support is parallel to the surface of the carrier (e.g. parallel to the main processing surface) the “thickness” of the layer formed on the surface of the support may be the same as the height of the layer.

In the following, various aspects of this disclosure will be illustrated.

Example 1 is a memory cell including: a capacitive memory structure, the capacitive memory structure including a first electrode, a second electrode, and a memory structure disposed between the first electrode and the second electrode; and a field-effect transistor structure, the field-effect transistor structure including a gate structure coupled to the capacitive memory structure, wherein the first electrode of the capacitive memory structure includes a first electrode material having a first work-function and the second electrode of the capacitive memory structure includes a second electrode material having a second work-function, wherein the first work-function is different from the second work-function.

In Example 2, the memory cell according to example 1 may optionally further include that an absolute value of a difference of the first work-function and the second work-function is greater than 0.1 electron-volts and less than 4 electron-volts.

In Example 3, the memory cell according to example 1 or 2 may optionally further include that the capacitive memory structure and the field-effect transistor structure are coupled with one another to form a capacitive voltage divider.

In Example 4, the memory cell according to any one of examples 1 to 3 may optionally further include that the gate structure of the field-effect transistor structure includes a gate electrode and a gate isolation separating the gate electrode from a channel region of the field-effect transistor structure, wherein the gate electrode is coupled to the first electrode of the capacitive memory structure.

In Example 5, the memory cell according to example 4 may optionally further include that the gate isolation extends from the channel region of the field-effect transistor structure to the gate electrode of the field-effect transistor structure.

In Example 6, the memory cell according to any one of examples 1 to 5 may optionally further include that the field-effect transistor structure includes a gate electrode layer and wherein the first electrode of the capacitive memory structure includes a first electrode layer, wherein the first electrode layer and the gate electrode layer are spatially separated from one another and electrically conductively connected to one another.

In Example 7, the memory cell according to any one of examples 1 to 6 may optionally further include that the field-effect transistor structure includes a gate electrode layer and wherein the first electrode of the capacitive memory structure includes a first electrode layer, wherein the first electrode layer and the gate electrode layer are in direct physical contact with one another.

In Example 8, the memory cell according to any one of examples 1 to 7 may optionally further include that the field-effect transistor structure includes a gate electrode, wherein the gate electrode and the first electrode of the capacitive memory structure are provided by a common electrode layer.

In Example 9, the memory cell according to any one of examples 1 to 8 may optionally further include that the memory structure includes one or more remanent-polarizable layers.

In Example 10, the memory cell according to example 9 may optionally further include that a material of the one or more remanent-polarizable layers includes at least one of the following: hafnium oxide, zirconium oxide, a mixture of hafnium oxide and zirconium oxide.

In Example 11, the memory cell according to any one of examples 1 to 10 may optionally further include that the memory structure includes one or more spontaneously-polarizable layers and one or more charge storage layers.

In Example 12, the memory cell according to any one of examples 1 to 11 may optionally further include that the first electrode material includes a basic material having a work-function associated therewith and a first doping material that increases the work-function of the basic material.

In Example 13, the memory cell according to example 12 may optionally further include that the second electrode material includes the basic material and a second doping material that decreases the work-function of the basic material.

In Example 14, the memory cell according to any one of examples 1 to 13 may optionally further include that at least one of the first electrode and the second electrode is a multilayer electrode, the multilayer electrode including one or more layers of a first material and one or more layers of a second material, wherein a work-function of the first material is different from a work-function of the second material.

In Example 15, the memory cell according to any one of examples 1 to 14 may optionally further include that the first electrode is provided by one or more electrode layers having a first total thickness.

In Example 16, the memory cell according to example 15 may optionally further include that the second electrode is provided by one or more electrode layers having a second total thickness that is different from (e.g., at least 1% difference, e.g., at least 2% difference, e.g., at least 5% difference) the first total thickness.

In Example 17, the memory cell according to any one of examples 1 to 16 may optionally further include that a thickness of the first electrode is configured to adapt the work-function of the first electrode material.

In Example 18, the memory cell according to any one of examples 1 to 17 may optionally further include that a thickness of the second electrode is configured to adapt the work-function of the second electrode material.

In Example 19, the memory cell according to any one of examples 1 to 17 may optionally further include that the first electrode includes a basic material and/or that the second electrode includes the/a basic material.

In Example 20, the memory cell according to example 19 may optionally further include that the basic material is or includes at least one of the following: a metal, a metal nitride, e.g., titanium, e.g., titanium nitride.

Example 21 is a capacitive memory structure including: a first electrode including a first electrode material having a first work-function; a second electrode including a second electrode material having a second work-function; and a memory structure disposed between the first electrode and the second electrode, wherein the first work-function of the first electrode material is different from the second work-function of the second electrode material.

In Example 22, the capacitive memory structure according to example 21 may optionally further include that the memory structure includes one or more remanent-polarizable layers.

In Example 23, the capacitive memory structure according to example 22 may optionally further include that each of the one or more remanent-polarizable layers includes a remanent polarizable material.

In Example 24, the capacitive memory structure according to any one of examples 21 to 23 may optionally further include that the memory structure includes one or more spontaneously-polarizable layers and one or more charge storage layers.

In Example 25, the capacitive memory structure according to any one of examples 21 to 24 may optionally further include that an absolute value of a difference of the first work-function and the second work-function is greater than 0.1 electron-volts and less than 4 electron-volts.

In Example 26, the capacitive memory structure according to any one of examples 21 to 25 may optionally further include that the capacitive memory structure is coupled to a field-effect transistor structure to form a capacitive voltage divider.

In Example 27, the capacitive memory structure according to example 26 may optionally further include that the field-effect transistor structure includes a gate electrode and a gate isolation separating the gate electrode from a channel region of the field-effect transistor structure, wherein the gate electrode is coupled to the first electrode.

In Example 28, the capacitive memory structure according to example 26 or 27 may optionally further include that the field-effect transistor structure includes a gate electrode layer and wherein the first electrode includes a first electrode layer, wherein the first electrode layer and the gate electrode layer are spatially separated from one another and electrically conductively connected to one another.

In Example 29, the capacitive memory structure according to example 26 or 27 may optionally further include that the field-effect transistor structure includes a gate electrode layer and wherein the first electrode includes a first electrode layer, wherein the first electrode layer and the gate electrode layer are in direct physical contact with one another.

In Example 30, the capacitive memory structure according to example 26 or 27 may optionally further include that the field-effect transistor structure includes a gate electrode, wherein the gate electrode and the first electrode are provided by a common electrode layer.

In Example 31, the capacitive memory structure according to any one of examples 21 to 30 may optionally further include that the first electrode material includes a basic material having a work-function associated therewith and a first doping material that increases the work-function of the basic material; and/or that the second electrode material includes the basic material and a second doping material that decreases the work-function of the basic material. In a similar way, the capacitive memory structure may optionally further include that the second electrode material includes a basic material having a work-function associated therewith and a first doping material that increases the work-function of the basic material; and/or that the first electrode material includes the basic material and a second doping material that decreases the work-function of the basic material. In some aspects, the capacitive memory structure according to any one of examples 21 to 30 may optionally further include that the first electrode material includes a basic material having a work-function associated therewith and a first doping material that modifies (e.g., increases or decreases) the work-function of the basic material; and/or that the second electrode material includes the basic material and a second doping material that modifies (e.g., decreases or increases) the work-function of the basic material.

In Example 32, the capacitive memory structure according to any one of examples 21 to 31 may optionally further include that at least one of the first electrode and the second electrode is a multilayer electrode, the multilayer electrode including one or more layers of a first material and one or more layers of a second material, wherein a work-function of the first material is different from a work-function of the second material.

In Example 33, the capacitive memory structure according to any one of examples 21 to 32 may optionally further include that the first electrode is provided by one or more electrode layers having a first total thickness and that the second electrode is provided by one or more electrode layers having a second total thickness that is different from the first total thickness.

In Example 34, the capacitive memory structure according to any one of examples 21 to 33 may optionally further include that a thickness of the first electrode and/or a thickness of the second electrode are/is configured to adapt the work-function of the first electrode material and the second electrode material respectively.

Example 35 is a method for forming a capacitive memory structure, the method including: forming a first electrode, the first electrode including a first electrode material having a first work-function; forming a memory structure over the first electrode; and forming a second electrode over the memory structure, the second electrode including a second electrode material having a second work-function different from the second work-function, wherein the first electrode, the memory structure, and the second electrode form a capacitive memory structure.

Example 36 is a method for forming a memory cell, the method including: forming a field-effect transistor structure; forming a first electrode coupled to a gate electrode of the field-effect transistor structure, the first electrode including a first electrode material having a first work-function; forming a memory structure over the first electrode; and forming a second electrode over the memory structure, the second electrode including a second electrode material having a second work-function different from the second work-function, wherein the first electrode, the memory structure, and the second electrode form a capacitive memory structure.

In Example 37, the method according to example 35 or 36 may optionally further include that forming the first electrode includes: depositing the first electrode material, or depositing a basic material and modifying the basic material to thereby form the first electrode material.

In Example 38, the method according to any one of examples 35 to 37 may optionally further include that forming the second electrode includes: depositing the second electrode material, or depositing a basic material and modifying the basic material to thereby form the second electrode material.

In Example 39, the method according to example 38 may optionally further include that modifying the basic material includes at least one of: doping the basic material with one or more dopants; intermixing the basic material with one or more additional materials; implanting ions into the basic material; modifying the microstructure of the basic material; modifying the surface roughness of the basic material; removing a portion of the basic material; and/or modifying the crystallographic phase of the basic material.

In Example 40, the method according to any one of examples 35 to 39 may optionally further include that forming the first electrode includes forming one or more first electrode layers with a predefined thickness having the first work-function associated therewith.

In Example 41, the method according to any one of examples 35 to 40 may optionally further include that forming the second electrode includes forming one or more second electrode layers with a predefined thickness having the second work-function associated therewith.

Example 42 is a memory cell including: a capacitive memory structure, the capacitive memory structure including a first electrode, a second electrode, and a memory structure disposed between the first electrode and the second electrode; and a field-effect transistor structure, the field-effect transistor structure comprising a gate structure coupled to the capacitive memory structure, wherein the first electrode of the capacitive memory structure and the second electrode of the capacitive memory structure are configured to generate an internal electric field within the capacitive memory structure to influence the memory structure disposed between the first electrode and the second electrode.

Example 43 is a capacitive memory structure including: a first electrode, a second electrode, and a memory structure disposed between the first electrode and the second electrode; and a field-effect transistor structure, wherein the first electrode of the capacitive memory structure and the second electrode of the capacitive memory structure are configured to generate an internal electric field within the capacitive memory structure to influence the memory structure disposed between the first electrode and the second electrode.

It is understood that examples 42 and 43 may be further configured as described herein, e.g., as described with reference to examples 1 to 41.

In some aspects, the absolute value of a difference of the first work-function and the second work-function may be greater than 0.15 electron-volts and less than 3 electron-volts. In some aspects, e.g., in the case that adapted materials are involved, the absolute value of a difference of the first work-function and the second work-function may be greater than 0.5 electron-volts and less than 4 electron-volts, e.g., greater than 1 electron-volts and less than 4 electron-volts.

While the invention has been particularly shown and described with reference to specific aspects, it should be understood by those skilled in the art that various changes in form and detail may be made therein without departing from the spirit and scope of the invention as defined by the appended claims. The scope of the invention is thus indicated by the appended claims and all changes, which come within the meaning and range of equivalency of the claims, are therefore intended to be embraced.

What is claimed is:

1. A memory cell comprising:
a capacitive memory structure, the capacitive memory structure comprising a first electrode, a second electrode, and a memory structure disposed between the first electrode and the second electrode; and
a field-effect transistor structure, the field-effect transistor structure comprising a gate structure coupled to the capacitive memory structure,
wherein the first electrode of the capacitive memory structure comprises a first electrode material having a first work-function and the second electrode of the capacitive memory structure comprises a second electrode material having a second work-function, wherein the first work-function is different from the second work-function.

2. Memory cell according to claim 1,
wherein an absolute value of a difference of the first work-function and the second work-function is greater than 0.1 electron-volts and less than 4 electron-volts.

3. Memory cell according to claim 1,
wherein the capacitive memory structure and the field-effect transistor structure are coupled with one another to form a capacitive voltage divider.

4. Memory cell according to claim 1,
wherein the gate structure of the field-effect transistor structure comprises a gate electrode and a gate isolation separating the gate electrode from a channel region of the field-effect transistor structure, wherein the gate electrode is coupled to the first electrode of the capacitive memory structure.

5. Memory cell according to claim 4,
wherein the gate isolation extends from the channel region of the field-effect transistor structure to the gate electrode of the field-effect transistor structure.

6. Memory cell according to claim 1,
wherein the field-effect transistor structure comprises a gate electrode layer and wherein the first electrode of the capacitive memory structure comprises a first electrode layer, wherein the first electrode layer and the gate electrode layer are spatially separated from one another and electrically conductively connected to one another.

7. Memory cell according to claim 1,
wherein the field-effect transistor structure comprises a gate electrode layer and wherein the first electrode of the capacitive memory structure comprises a first electrode layer, wherein the first electrode layer and the gate electrode layer are in direct physical contact with one another.

8. Memory cell according to claim 1,
wherein the field-effect transistor structure comprises a gate electrode, wherein the gate electrode and the first electrode of the capacitive memory structure are provided by a common electrode layer.

9. Memory cell according to claim 1,
wherein the memory structure comprises one or more remanent-polarizable layers.

10. Memory cell according to claim 9,
wherein a material of the one or more remanent-polarizable layers comprises at least one of the following:
hafnium oxide,
zirconium oxide,
a mixture of hafnium oxide and zirconium oxide.

11. Memory cell according to claim 1,
wherein the memory structure comprises one or more spontaneously-polarizable layers and one or more charge storage layers.

12. Memory cell according to claim 1,
wherein the first electrode material comprises a basic material having a work-function associated therewith and a first doping material that increases the work-function of the basic material, and wherein the second electrode material comprises the basic material and a second doping material that decreases the work-function of the basic material; or
wherein the first electrode material comprises a basic material having a work-function associated therewith and a first doping material that decreases the work-function of the basic material, and wherein the second electrode material comprises the basic material and a second doping material that increases the work-function of the basic material.

13. Memory cell according to claim 1,
wherein at least one of the first electrode and the second electrode is a multilayer electrode, the multilayer electrode comprising one or more layers of a first material and one or more layers of a second material, wherein a work-function of the first material is different from a work-function of the second material.

14. Memory cell according to claim 1,
wherein the first electrode is provided by one or more electrode layers having a first total thickness and wherein the second electrode is provided by one or more electrode layers having a second total thickness that is different from the first total thickness.

15. Memory cell according to claim 1,
wherein a thickness of the first electrode and/or a thickness of the second electrode are/is configured to adapt the work-function of the first electrode material and the second electrode material respectively.

16. A capacitive memory structure comprising:
a first electrode comprising a first electrode material having a first work-function;
a second electrode comprising a second electrode material having a second work-function; and
a memory structure disposed between the first electrode and the second electrode,
wherein the first work-function of the first electrode material is different from the second work-function of the second electrode material.

17. Capacitive memory structure according to claim 16,
wherein the memory structure comprises one or more remanent-polarizable layers, or
wherein the memory structure comprises one or more spontaneously-polarizable layers and one or more charge storage layers.

18. Capacitive memory structure according to claim 16,
wherein the capacitive memory structure is coupled to a field-effect transistor structure to form a capacitive voltage divider.

19. A method for forming a capacitive memory structure, the method comprising:
forming a first electrode, the first electrode comprising a first electrode material having a first work-function;
forming a memory structure over the first electrode; and
forming a second electrode over the memory structure, the second electrode comprising a second electrode material having a second work-function different from the second work-function, wherein the first electrode, the memory structure, and the second electrode form a capacitive memory structure.

20. Method according to claim 19,
wherein forming the first electrode comprises:
depositing the first electrode material, or
depositing a basic material and modifying the basic material to thereby form the first electrode material; and/or
wherein forming the second electrode comprises:
depositing the second electrode material, or
depositing a basic material and modifying the basic material to thereby form the second electrode material.
